(19) United States
(12) Patent Application Publication
(10) Pub. No.: US 2026/0206297 A1
(43) Pub. Date: Jul. 16, 2026

(54) SEMICONDUCTOR DEVICE INCLUDING A SENSOR DIODE STRUCTURE

(71) Applicant: Infineon Technologies Dresden AG & Co. KG, Dresden (DE)

(72) Inventor: Armin Tilke, Dresden (DE)

(21) Appl. No.: 19/443,113

(22) Filed: Jan. 8, 2026

(30) Foreign Application Priority Data
Jan. 14, 2025 (DE) 102025101077.3

(51) Int. Cl. H10D 84/80; H10D 8/00; H10D 8/01; H10D 12/00; H10D 12/01; H10D 30/01; H10D 62/83; H10D 62/832; H10D 64/27; H10D 62/10

(52) U.S. Cl. CPC H10D 84/811; H10D 8/045; H10D 8/411; H10D 12/031; H10D 12/411; H10D 30/027; H10D 62/83; H10D 62/8325; H10D 64/513; H10D 64/514; H10D 64/518; H10D 62/124

(57) ABSTRACT

A semiconductor device includes a silicon carbide (SiC) semiconductor substrate including a transistor cell area and a sensor area at a first surface of the SiC semiconductor substrate. The semiconductor device further includes a gate trench in the transistor cell area. A gate dielectric and a gate electrode are arranged in the gate trench. The semiconductor device further includes a sensor trench in the sensor area. A sensor trench dielectric is arranged at a bottom side of the sensor trench. The semiconductor device further includes a sensor diode structure on the sensor trench dielectric. A thickness of the sensor trench dielectric is larger than a thickness of the gate dielectric. A vertical distance from a bottom side of the sensor trench to the first surface is equal to or larger than a vertical distance from a bottom side of the gate trench to the first surface.

### TECHNICAL FIELD

The present disclosure relates to a semiconductor device, in particular to a semiconductor device including a silicon carbide (SiC) semiconductor substrate and a sensor diode structure.

### BACKGROUND

Technology development of SiC semiconductor devices, e.g. power transistors such as insulated gate field effect transistors (IGFETs) formed as metal oxide semiconductor field effect transistors (MOSFETs) or insulated gate bipolar transistors (IGBTs) aims at reducing an area-specific on-state resistance without adversely affecting reliability or a blocking voltage capability between source anddrain or between emitter and collector. During operation of the SiC semiconductor devices, a wide variety of switching states occur, in which large power losses are converted into heat. Switching states associated with large power losses are critical in view of the rise of the temperature inside the device that may be damaged or even be destroyed by overheating. In order to protect the semiconductor devices from damage caused by critical switching states, temperature sensors are often used. Ideally, the temperature sensors are positioned as close as possible to or are embedded in the transistor cell area in order that a temperature rise on account of energy loss converted into heat is detected early and rapidly. Thereby the transistor is turned off in good time before self-destruction on account of overheating by means of an auxiliary circuit such as a logic circuit. Integration of a sensor diode structure into a SiC semiconductor device is challenging in view of meeting reliability constraints of the sensor diode structure based on the manufacturing process flow of the SiC semiconductor device.

There is a need to improve semiconductor devices including a silicon carbide (SiC) semiconductor substrate and a sensor diode structure.

### SUMMARY

An example of the present disclosure relates to a semiconductor device comprising a silicon carbide (SiC) semiconductor substrate including a transistor cell area and a sensor area at a first surface of the SiC semiconductor substrate. The semiconductor device further includes a gate trench in the transistor cell area. The semiconductor device further includes a gate dielectric and a gate electrode in the gate trench. The semiconductor device further includes a sensor trench in the sensor area. The semiconductor device further includes a sensor trench dielectric at a bottom side of the sensor trench. The semiconductor device further includes a sensor diode structure on the sensor trench dielectric. A thickness of the sensor trench dielectric is larger than a thickness of the gate dielectric. A vertical distance from a bottom side of the sensor trench to the first surface is equal to or larger than a vertical distance from a bottom side of the gate trench to the first surface.

Another example of the present disclosure relates to a method of manufacturing a semiconductor device in a silicon carbide (SiC) semiconductor substrate including a transistor cell area and a sensor area at a first surface of the SiC semiconductor substrate. The method includes forming a gate trench in the transistor cell area. The method further includes forming a gate dielectric and a gate electrode in the gate trench. The method further includes forming a sensor trench in the sensor area. The method further includes forming a sensor trench dielectric at a bottom side of the sensor trench. The method further includes forming a sensor diode structure on the sensor trench dielectric. A thickness of the sensor trench dielectric is larger than a thickness of the gate dielectric. A vertical distance from a bottom side of the sensor trench to the first surface is equal to or larger than a vertical distance from a bottom side of the gate trench to the first surface.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 schematically and exemplarily illustrates a cross-sectional view of a configuration example of a semiconductor device including a SiC semiconductor substrate.

FIG. 2 schematically and exemplarily illustrates a cross-sectional view of a further configuration example of a semiconductor device including a SiC semiconductor substrate.

FIG. 3 is an exemplary process illustration of manufacturing a semiconductor device including a SiC semiconductor substrate.

FIGS. 4A to 4L are cross-sectional views for illustrating exemplary process features of manufacturing semiconductor devices including a SiC semiconductor substrate.

FIG. 5 is a cross-sectional view for illustrating an exemplary process feature of manufacturing semiconductor devices including a SiC semiconductor substrate.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms "having", "containing", "including", "comprising" and the like are open, and the terms indicate the presence of stated structures, elements or features but do not preclude the presence of additional elements or features. The articles "a", "an" and "the" are intended to include the plural as well as the singular, unless the context clearly indicates otherwise.

The term "electrically connected" may describe a permanent low-resistive connection between electrically connected elements, for example a direct contact between the concerned elements or a low-resistive connection via a metal and/or heavily doped semiconductor material. The term "electrically coupled" may include that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a ≤ y ≤ b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term "on" is not to be construed as meaning only "directly on". Rather, if one element is positioned "on" another element (e.g., a layer is "on" another layer or "on" a substrate), a further component (e.g., a further layer) may be positioned between the two elements (e.g., a further layer may be positioned between a layer and a substrate if the layer is "on" said substrate).

The Figures may illustrate relative doping concentrations by indicating "-" or "+" next to the doping type "n" or "p". For example, "n-" means a doping concentration which is lower than the doping concentration of an "n"-doping region while an "n+"-doping region has a higher doping concentration than an "n"-doping region. Doping regions of the same relative doping concentration do not necessarily have the same absolute doping concentration. For example, two different "n"-doping regions may have the same or different absolute doping concentrations. Two directly adjoining doping regions of the same conductivity type and with different dopant concentrations form a unipolar junction, e.g., an n/n+ or p/p+ junction along a boundary surface between the two doping regions. At the unipolar junction a dopant concentration profile orthogonal to the unipolar junction may show a step or a turning point, at which the dopant concentration profile changes from being concave to convex, or vice versa.

The description and drawings merely illustrate the principles of the disclosure. Furthermore, all examples recited herein are principally intended expressly to be only for illustrative purpose to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

A configuration example of a semiconductor device includes a silicon carbide (SiC) semiconductor substrate having a transistor cell area and a sensor area at a first surface of the SiC semiconductor substrate. A gate trench is included in the transistor cell area. A gate dielectric and a gate electrode are included in the gate trench. The semiconductor device further includes a sensor trench in the sensor area. A sensor trench dielectric is included at a bottom side of the sensor trench. A sensor diode structure is included on the sensor trench dielectric. A thickness of the sensor trench dielectric may be larger than a thickness of the gate dielectric. A vertical distance from a bottom side of the sensor trench to the first surface may be equal to or larger than a vertical distance from a bottom side of the gate trench of the first surface.

The semiconductor device may be part of an integrated circuit or may be a discrete semiconductor device or a semiconductor module, for example. The semiconductor device may be or may include an insulated gate field effect transistor (IGFET) such as a metal oxide semiconductor field effect transistor (MOSFET) or an insulated gate bipolar transistor (IGBT) or a junction field effect transistor (JFET), for example. The semiconductor device may be a vertical semiconductor device having a load current flow between the first surface and a second surface opposite to the first surface along the vertical direction. The vertical power semiconductor device may be configured to conduct currents of more than 1 A, or more than 10 A, or more than 30 A, or more than 50 A, or more than 75 A, or more than 100 A, or even more than 1000 A, and may be further configured to block voltages between load electrodes, e.g. between collector and emitter of an IGBT, or between drain and source of a MOSFET, in the range of several hundreds of up to several thousands of volts, e.g. 400 V, 650 V, 1.2 kV, 1.7 kV, 3.3 kV, 4.5 kV, 5.5 kV, 6 kV, 6.5 kV, 10 kV. The blocking voltage may correspond to a voltage class specified in a datasheet of the power semiconductor device, for example.

The SiC semiconductor substrate may be based on a crystalline SiC material. The crystalline SiC material may have a hexagonal crystal lattice, by way of example. For example, the semiconductor material may be 2H-SiC (SiC of the 2H polytype), 6H-SiC or 15R-SiC. According to an example, the semiconductor material is silicon carbide of the 4H polytype (4H-SiC). The SiC semiconductor substrate may include or consist of a semiconductor base substrate, e.g. a wafer portion, having none, one or more than one semiconductor layers, e.g. epitaxially grown layers, thereon. One of the semiconductor layers may be a doped semiconductor layer of a current spread layer, for example.

The first surface may define a front surface or a top surface of the SiC semiconductor substrate, and the SiC semiconductor substrate may further include a second surface that may be a back surface or a rear surface of the SiC semiconductor substrate, for example. The SiC semiconductor substrate may be attached to a lead frame via the second surface, for example. Over the first surface of the SiC semiconductor substrate, bond pads may be arranged and bond wires may be bonded on the bond pads, for example.

For realizing a desired current carrying capacity, the semiconductor device may be designed by a plurality of parallel-connected SiC semiconductor device cells. The parallel-connected SiC semiconductor device cells may, for example, be SiC semiconductor device cells formed in the shape of a strip or a strip segment. Of course, the SiC semiconductor device cells can also have any other shape, e.g. circular, elliptical, polygonal such as hexagonal or octahedral. The semiconductor device cells may be arranged in the transistor cell area of the SiC semiconductor substrate. The transistor cell area may be an area where an emitter region of an IGBT (or a source region of a MOSFET) and a collector region of an IGBT (or a drain region of a MOSFET) are arranged opposite to one another along a vertical direction. In the transistor cell area, a load current may enter or exit the SiC semiconductor substrate of the semiconductor device, e.g. via contact plugs or contact lines on the top surface. The semiconductor device may further include an edge termination area that may include a termination structure. In a blocking mode or in a reverse biased mode of the semiconductor device, the blocking voltage between the transistor cell area and a field-free region laterally drops across the termination structure. The termination structure may have a higher or a slightly lower voltage blocking capability than the transistor cell area. The termination structure may include a junction termination extension (JTE) with or without a variation of lateral doping (VLD), one or more laterally separated guard rings, or any combination thereof, for example.

The sensor area of the semiconductor device may laterally adjoin the transistor cell area for achieving a beneficial thermal coupling between the transistor cell area and the sensor area. For example, the sensor area may be completely or partly laterally surrounded by the transistor cell area. For example, no functional device elements, e.g. other circuit parts, may be arranged between sensor area and the transistor cell area.

The gate dielectric in the gate trench may include or consist of one layer or a combination of layers, e.g. a layer stack of dielectric layers, for example oxide layers such as thermal oxide layers or deposited oxide layers, e.g. tetraethyl orthosilicate (TEOS), undoped silicate glass (USG), phosphosilicate glass (PSG), boron silicate glass (BSP), borophosphosilicate glass (BPSG), nitride layers, high-k dielectric layers or low-k dielectric layers. A vertical extension of the gate trench may be in a range from 0.3 μm to 5 μm, e.g., in a range from 0.5 μm to 2 μm. Sidewalls of the gate trench may be perpendicular to the first surface or may taper with increasing distance to the first surface. A lateral width of the gate trench may be in a range from 500 nm to 5 μm, e.g., in a range from 1 μm to 3 μm. The gate electrode may include or consist of one electrode material or a combination of electrode materials, for example a doped semiconductor material (e.g., a degenerate doped semiconductor material) such as doped polycrystalline silicon, metal or metal compounds.

Similar to the gate dielectric, the sensor trench dielectric may include or consist of one layer or a combination of layers, e.g. a layer stack of dielectric layers, for example oxide layers such as thermal oxide layers or deposited oxide layers, e.g. tetraethyl orthosilicate (TEOS), undoped silicate glass (USG), phosphosilicate glass (PSG), boron silicate glass (BSP), borophosphosilicate glass (BPSG), nitride layers, high-k dielectric layers or low-k dielectric layers.

The sensor diode structure may include one or more pn junction diodes connected to one another, for example. A material of the sensor diode structure may include crystalline, polycrystalline and/or amorphous semiconductor material(s) that may be partly n- and p-doped for realizing the pn junction diodes.

The semiconductor devices disclosed herein may allow for a beneficial integration of a sensor diode structure into a semiconductor device including a SiC semiconductor substrate. The sensor diode structure may not only be integrated into the process flow of manufacturing the semiconductor device, e.g. transistor, in a beneficial way by concurrently using process features, but may also allow for improving reliability by including the sensor trench dielectric at the bottom side of the sensor trench. This may allow for an improved ESD ruggedness and/or fast switching applications. Using the gate trench processing also for processing of the sensor trench saves processing complexity and costs. It enables to provide a sufficiently thick oxide beneath the sensor element in order to achieve a sufficient electrical isolation towards the underlying potential, e.g. source potential. This isolation is of importance in the case of ESD events (electrostatic discharge events), since here the high electric field may lead to a breakdown towards source if the oxide beneath the sensor is not thick enough. Moreover, using the gate trench processing simultaneously for sensor trench processing also allows to place the sensor deeper into the SiC semiconductor substrate for improving the thermal coupling between the sensor and the SiC chip.

For example, the sensor trench dielectric may include a first dielectric layer and a second dielectric layer. The first dielectric layer may be arranged between the bottom side of the sensor trench and the second dielectric layer.

For example, the first dielectric layer may be a nitride layer and the second dielectric layer may be an oxide layer. For example, a material of the first dielectric layer may act as an etch stop for the material of the second dielectric layer. Therefore, a material of the second dielectric layer may be a dielectric material that is selectively etchable with respect to a material of the first dielectric layer. For example, a material of the first dielectric layer may be a material that is selectively etchable to an oxide such as an oxide of silicon.

For example, the semiconductor device may further include the gate dielectric arranged between the bottom side of the sensor trench and the first dielectric layer. For example, a top side of the gate dielectric may adjoin a bottom side of the first dielectric layer.

For example, the semiconductor device may further include a shielding layer structure. The shielding layer structure may include a first part and a second part laterally spaced from one another. The first part of the shielding layer structure may adjoin the bottom side of the gate trench. The second part of the shielding layer structure may adjoin the bottom side of the sensor trench. The first part of the shielding layer structure may support shielding the gate dielectric in the gate trench structure from high electric fields. For example, the shielding layer structure may include one or more doped shielding sub-layers overlapping one another, for example. The shielding layer structure may have a conductivity type other than the conductivity type of the source or emitter region, e.g. a p-type for an n-channel MOSFET or IGBT, or an n-type for a p-channel MOSFET or IGBT.

For example, the shielding layer structure may extend along a first sidewall of the gate trench to the first surface. The semiconductor device may further include a body region adjoining a second sidewall of the gate trench. For example, a channel region may be formed in the body region along one of two opposite sidewalls of the gate trench.

For example, the semiconductor device may further include a first sensor pin and a second sensor pin. The first and second sensor pins may be each electrically isolated from pins of the transistor cell area. Pins of the transistor cell area may include, for example, a gate pin, a first load pin such as a source or emitter pin and a second load pin such as a drain or collector pin. The pins may be pins of a chip package, for example.

For example, the sensor diode structure may include a pn junction diode or a plurality of pn junction diodes electrically connected in series via anode to cathode. The serial connection via anode to cathode allows for increasing the forward voltage of the sensor diode structure. This corresponds to a sum of forward voltages that may be adjusted to voltage requirements of the readout circuitry, for example.

For example, the pn junction diode or the plurality of pn junction diodes are lateral pn junction diodes. In lateral pn junction diodes, a lateral direction may be perpendicular to a plane of the pn junction.

For example, the sensor diode structure may include polycrystalline and/or amorphous silicon, e.g. p- and n-doped portions of polycrystalline and/or amorphous silicon adjoining one another.

For example, a top side of the polycrystalline and/or amorphous silicon may be arranged at or below the first surface of the SiC semiconductor substrate.

For example, the polycrystalline and/or amorphous silicon may vertically extend from below the first surface of the SiC semiconductor substrate to over the first surface of the SiC semiconductor substrate.

For example, a bottom side of the polycrystalline and/or amorphous silicon is arranged at or over the first surface of the SiC semiconductor substrate.

For example, the semiconductor device may further include an intermediate dielectric layer adjoining the first surface of the SiC semiconductor substrate. A thickness of the polycrystalline and/or amorphous silicon may be larger than a thickness of the intermediate dielectric layer. If the sensor polysilicon and/or amorphous layer is made thicker, its resistivity is dropping and the sensor accuracy can be increased.

For example, the sensor diode structure may be a temperature sensor device configured to measure the temperature of the semiconductor device. For example, the forward voltage drop of the sensor diode structure may be sensed by an auxiliary circuit such as a logic circuit in view of a decrease of the forward voltage drop with increasing temperature. The auxiliary circuit may initiate a turn-off of the transistor when the sensed forward voltage drop falls below a predetermined threshold voltage, for example. For example, the reverse current of the sensor diode structure may be sensed by an auxiliary circuit such as a logic circuit in view of an increase of the reverse current with increasing temperature. The auxiliary circuit may initiate a turn-off of the transistor when the sensed reverse current exceeds a predetermined threshold current, for example.

Details with respect to structure, or function, or technical benefit of features described above with respect to a semiconductor device such as a FET, or IGBT likewise apply to the exemplary methods described further below. Processing the SiC semiconductor substrate may comprise one or more optional additional features corresponding to one or more aspects mentioned in connection with the proposed concept or one or more examples described above or below.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub–acts, -functions, -processes, -operations or –steps, respectively. Such sub acts may be included and part of the disclosure of this single act unless explicitly excluded.

An example relates to a method of manufacturing a semiconductor device in a silicon carbide (SiC) semiconductor substrate including a transistor cell area and a sensor area at a first surface of the SiC semiconductor substrate. The method includes forming a gate trench in the transistor cell area. The method further includes forming a gate dielectric and a gate electrode in the gate trench. The method further includes forming a sensor trench in the sensor area. The method further includes forming a sensor trench dielectric at a bottom side of the sensor trench. The method further includes forming a sensor diode structure on the sensor trench dielectric. A thickness of the sensor trench dielectric may be larger than a thickness of the gate dielectric. A vertical distance from a bottom side of the sensor trench to the first surface may be equal to or larger than a vertical distance from a bottom side of the gate trench to the first surface.

For example, the gate trench and the sensor trench may be concurrently formed, e.g. by one or more masked etch processes concurrently etching the gate and sensor trenches.

For example, the method may further include forming a shielding layer structure including a first part and a second part laterally spaced from one another. The shielding layer structure may be formed by at least one ion implantation process before forming the gate trench and the sensor trench. The first part of the shielding layer structure may adjoin the bottom side of the gate trench. The second part of the shielding layer structure may adjoin the bottom side of the sensor trench.

For example, the sensor trench dielectric may be formed after forming the gate electrode. Forming the sensor trench dielectric may include forming a first dielectric layer and forming a second dielectric layer. The first dielectric layer may be arranged between the bottom side of the sensor trench and the second dielectric layer.

For example, the method may further include selectively etching of a part of the second dielectric layer to the first dielectric layer.

For example, forming the sensor diode structure may include forming a layer including polycrystalline and/or amorphous silicon over the sensor trench dielectric. The method may further include selectively etching of a part of the layer including polycrystalline and/or amorphous silicon to the first dielectric layer.

In some of the illustrated examples, n-channel FETs or IGBTs are illustrated. However, the examples described herein may also be applied to p-channel devices, e.g. p-channel MOSFETs or p-channel IGBTs. For example, dopants in a semiconductor substrate comprising SiC may include Al, B, Be, Ga, or any combination thereof for p-type doping, and N, P, or any combination thereof for n-type doping. Instead of n- or p-channel FETs or IGBTs, the examples may also be applied to JFETs.

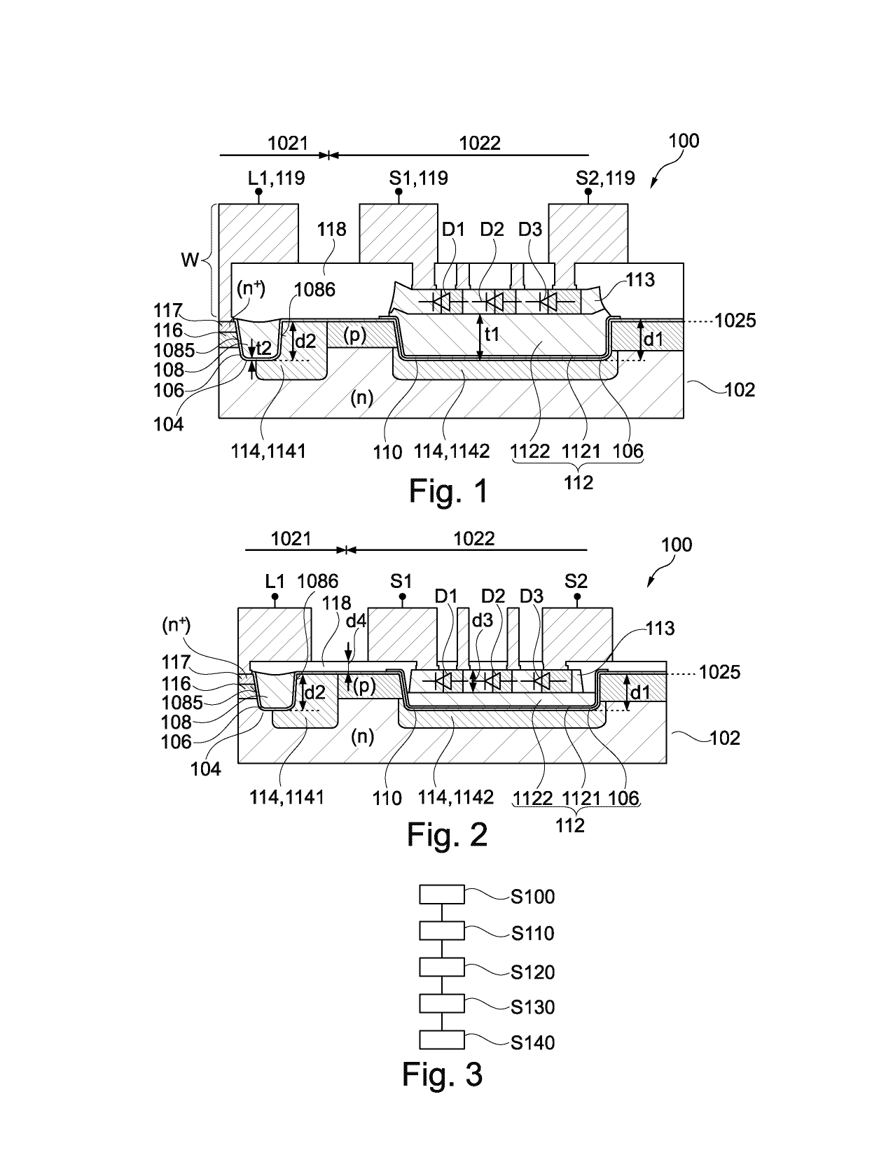

The schematic cross-sectional view of FIG. 1 illustrates an example of semiconductor device 100 configured as an n-channel SiC MOSFET including a SiC semiconductor substrate 102.

In the cross-sectional view of FIG. 1, portions of a transistor cell area 1021 and a sensor area 1022 at a first surface 1025 of the SiC semiconductor substrate 102 are illustrated.

In the transistor cell area 1021, an exemplary transistor cell layout is illustrated. Other transistor cell layouts may as well be used. A gate trench 104 in the transistor cell area 1021 extends into the SiC semiconductor substrate 102 from the first surface 1025. A gate electrode 108 in the gate trench 104 is separated and electrically isolated from a surrounding part of the SiC semiconductor substrate 102 by a gate dielectric 106. A p-doped body region 116 and an n⁺-doped source or emitter region 117 adjoin a first sidewall 1085 of the gate trench 108, respectively. A first part 1141 of a p-doped shielding layer structure 114 adjoins a bottom side of the gate trench 104 and extends along a second sidewall 1086 of the gate trench 104 up to the first surface 1025.

In the sensor area 1022, a sensor trench 110 extends into the SiC semiconductor substrate 102 from the first surface 1025. A sensor diode structure 113 is separated and electrically isolated from the SiC semiconductor substrate 102 by a sensor trench dielectric 112. A second part 1142 of the p-doped shielding layer structure 114 is laterally spaced from the first part 1141 of the p-doped shielding layer structure 114 and adjoins the bottom side of the sensor trench 110. The sensor trench dielectric 112 includes a first dielectric layer 1121 and a second dielectric layer 1122. The first dielectric layer 1121 is arranged between the bottom side of the sensor trench 110 and the second dielectric layer 1122. The gate dielectric 106 also forms part of the sensor trench dielectric 112 and is arranged between the bottom side of the sensor trench 110 and the first dielectric layer 1121. A thickness t1 of the sensor trench dielectric 112 is larger than a thickness t2 of the gate dielectric 106. A vertical distance d1 from a bottom side of the sensor trench 110 to the first surface 1025 is equal to or larger than a vertical distance d2 from a bottom side of the gate trench 104 to the first surface 1025.

The sensor diode structure 113 includes a plurality of pn junction diodes D1, D2, D3 electrically connected in series via anode to cathode. The pn junction diodes D1, D2, D3 are lateral pn junction diodes. In the configuration example illustrated in FIG. 1, a bottom side of a material of the pn junction diodes D1, D2, D3, e.g. polycrystalline and/or amorphous silicon, is arranged at or over the first surface 1025 of the SiC semiconductor substrate 102. In one example (not illustrated), one or more series-connected diodes are connected in antiparallel to the plurality of pn junction diodes D1, D2, D3.

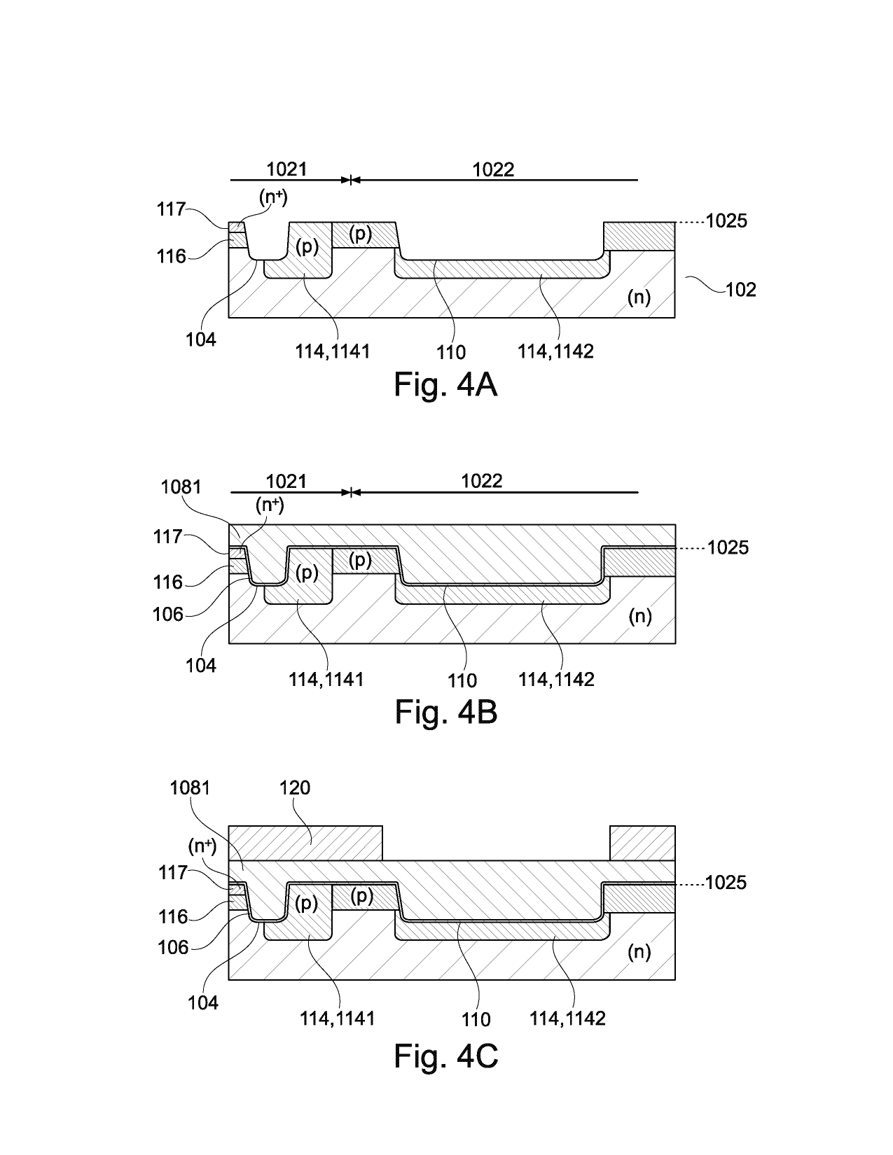

A wiring area W is arranged over the first surface 1025 of the SiC semiconductor substrate 102. The wiring area W includes an intermediate dielectric layer 118 on the first surface 1025 of the SiC semiconductor substrate 102. A wiring layer 119 is arranged on the intermediate dielectric layer 118. The wiring layer 119 is patterned into separate parts for forming electrodes corresponding to pins of a chip package. The electrodes extend through openings in the intermediate dielectric layer 118 for providing an electric contact to device elements. A first load electrode or pin L1 is electrically connected to the source or emitter region 117. The first load electrode or pin L1 may as well be electrically connected to the body region 116 and/or the first part 1141 of the p-doped shielding layer structure 114 in other parts at the first surface 1025 of the SiC semiconductor substrate 102 that are not illustrated in FIG. 1. A first sensor electrode or pin S1 is electrically connected to a cathode of the first diode D1. A second sensor electrode or pin S2 is electrically connected to an anode of the third diode D3. The connection may be formed by contact plugs or lines in the intermediate dielectric layer 118. In addition to the contact plugs or lines, also part of the wiring level 119 used for the electrode pins S1, S2 may contribute to the electrical connection between the diodes (not illustrated in FIG. 1, see FIG. 2).

The schematic cross-sectional view of FIG. 2 illustrates a further example of a semiconductor device 100 configured as an n-channel SiC MOSFET including a SiC semiconductor substrate 102.

Other than the sensor diode structure 113 of the configuration example illustrated in FIG. 1, the sensor diode structure 113 vertically extends from below the first surface 1025 of the SiC semiconductor substrate to the first surface 1025 of the SiC semiconductor substrate 102. A top side of the sensor diode structure 113 may be located at or close to the first surface 1025 (see FIG. 2). In further examples not illustrated in FIG. 2, the top side of the sensor diode structure 113 may also be located below the first surface 1025, or over the first surface 1025. A thickness d3 of the material of the sensor diode structure 113 is larger than a thickness d4 of the intermediate dielectric layer 118.

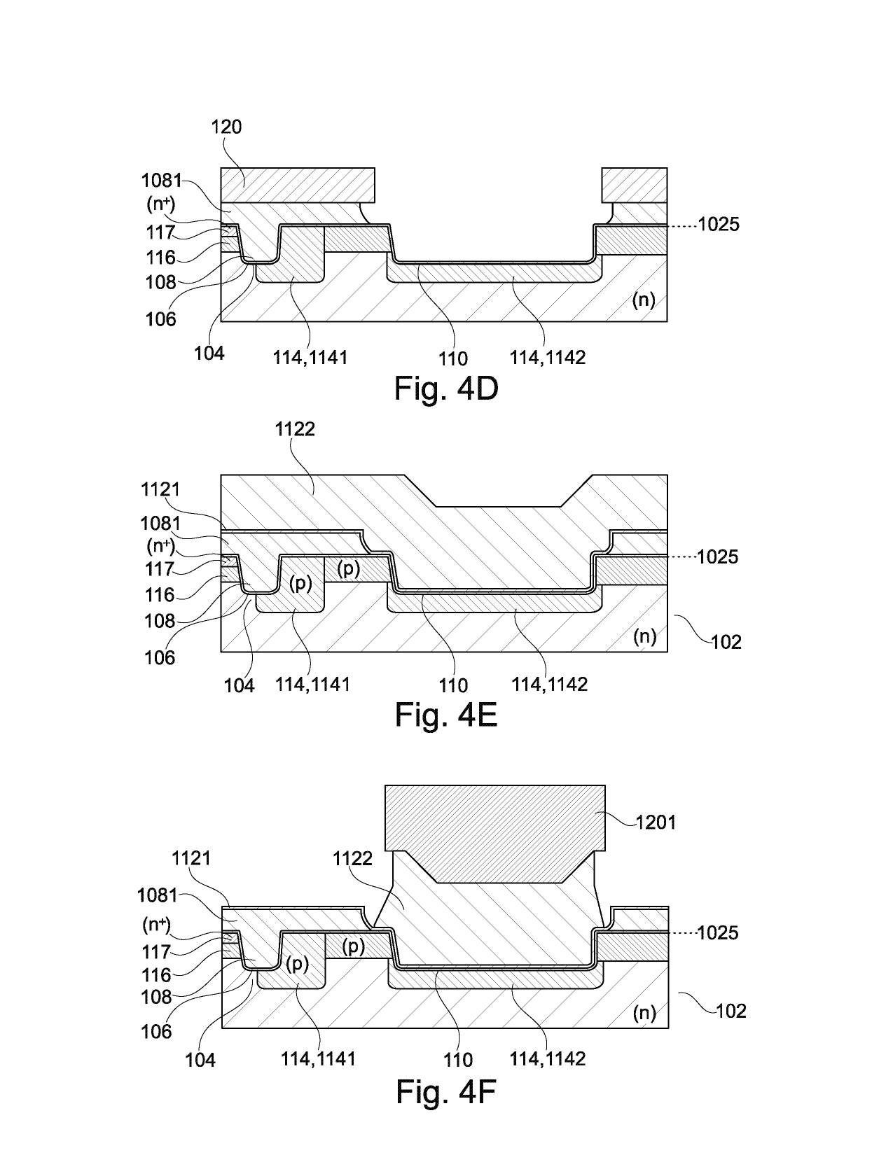

An example of a method of manufacturing a semiconductor device in a silicon carbide (SiC) semiconductor substrate including a transistor cell area and a sensor area is illustrated by referring to the flowchart of FIG. 3.

Process feature S100 includes forming a gate trench in the transistor cell area.

Process feature S110 includes forming a gate dielectric and a gate electrode in the gate trench.

Process feature S120 includes forming a sensor trench in the sensor area.

Process feature S130 includes forming a sensor trench dielectric at a bottom side of the sensor trench.

Process feature S140 includes forming a sensor diode structure on the sensor trench dielectric, wherein a thickness of the sensor trench dielectric is larger than a thickness of the gate dielectric, and wherein a vertical distance from a bottom side of the sensor trench to the first surface is equal to or larger than a vertical distance from a bottom side of the gate trench to the first surface.

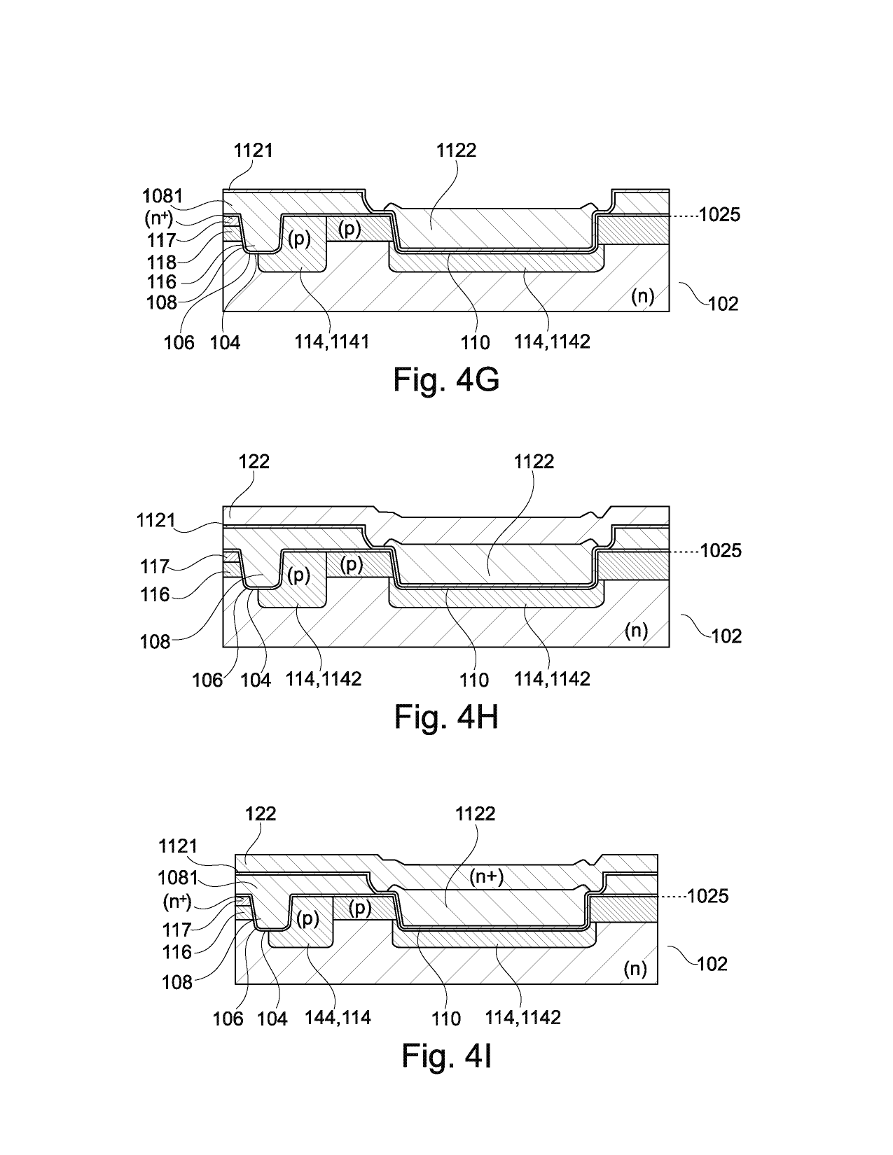

The schematic cross-sectional views of FIGS. 4A to 4L schematically and exemplarily illustrate process features for forming a semiconductor device according to the examples disclosed herein.

Referring to FIG. 4A, an n⁺-doped source or emitter region 117, a p-doped body region 116 and a p-doped shielding layer structure 114 are formed in the SiC semiconductor substrate 102 by introducing dopants into the SiC semiconductor substrate 102, e.g. by masked ion implantation process(es). Thereafter the gate trench 104 and the sensor trench 110 are concurrently formed, e.g. by a masked etched process. The gate trench 104 is formed in the transistor cell area 1021, and the sensor trench 110 is formed in the sensor area 1022. Etching the gate trench 104 removes part of the p-doped shielding layer structure 114 in the transistor cell area 1021 and ends before a bottom side of the p-doped shielding layer structure 114.

Referring to FIG. 4B, the gate dielectric 106 is formed in the gate trench 104. The gate dielectric 106 is also formed on the first surface 1025 and in the sensor trench 110. A gate electrode material 1081 is formed on the gate dielectric 106.

Referring to FIG. 4C, an etch mask pattern 120, e.g. a resist mask pattern, is formed on the gate electrode material 1081.

Referring to FIG. 4D, the gate electrode material 1081 is partly removed by an etch process using the etch mask pattern 120. The gate electrode 108 formed of the gate electrode material 1081 remains in the gate trench 104.

Referring to FIG. 4E, the etch mask pattern 120 is removed and a first dielectric layer 1121, e.g. a nitride layer, and a second dielectric layer 1122, e.g. a field oxide layer, are formed over SiC semiconductor substrate 102.

Referring to FIG. 4F, an etch mask pattern 1201, e.g. a resist mask pattern, is formed on the second dielectric layer 1122. The second dielectric layer 1122 is patterned using the etch mask pattern 1201. The second dielectric layer 1122 remains in the sensor trench 110.

Referring to FIG. 4G, the etch mask pattern 1201 is removed and the second dielectric layer 1122 is further recessed.

Referring to FIG. 4H, a sensor diode layer 122, e.g. an undoped or lightly doped polycrystalline and/or amorphous silicon layer, is formed over the sensor trench dielectric 112, e.g. by a layer deposition process.

Referring to FIG. 4I, the sensor diode layer 122 is doped with n-type dopants by introducing the n-type dopants into the sensor diode layer 122, e.g. by one or more ion implantation processes.

Referring to FIG. 4J, an etch mask pattern 1202, e.g. a resist mask pattern, is formed on the doped sensor diode layer 122. The doped sensor diode layer 122 is patterned using the etch mask pattern 1202. The doped sensor diode layer 122 remains on the second dielectric layer 1122.

Referring to FIG. 4K, the etch mask pattern 1202 and the first dielectric layer 1121 outside the sensor trench 110 are removed.

Referring to FIG. 4L, an etch mask pattern 1203 is formed on and around the doped sensor diode layer 122. The gate electrode material 1081 is removed over the first surface 1025 and remains in the gate trench 104 as the gate electrode 108.

The semiconductor substrate illustrated in FIG. 4L is further processed toward the layout illustrated in FIG. 1 by removing the etch mask pattern 1203, and by introducing p-type dopants into parts of the doped sensor diode layer 122 for forming the pn junction diodes D1, D2 and D3, e.g. by a masked ion implantation process. The intermediate dielectric layer 118 is formed over the first surface 1025, e.g. by a dielectric layer deposition process followed by a planarization process. After forming contact openings in the intermediate dielectric layer 118, a wiring layer 119 is formed on the intermediate dielectric layer 118 and in the openings of the intermediate dielectric layer 118. The wiring layer 119 is patterned for defining electrodes corresponding to the pins L1, S1, S2, and for electrically connecting anode to cathode of adjoining pn junction diodes of the sensor diode structure 113.

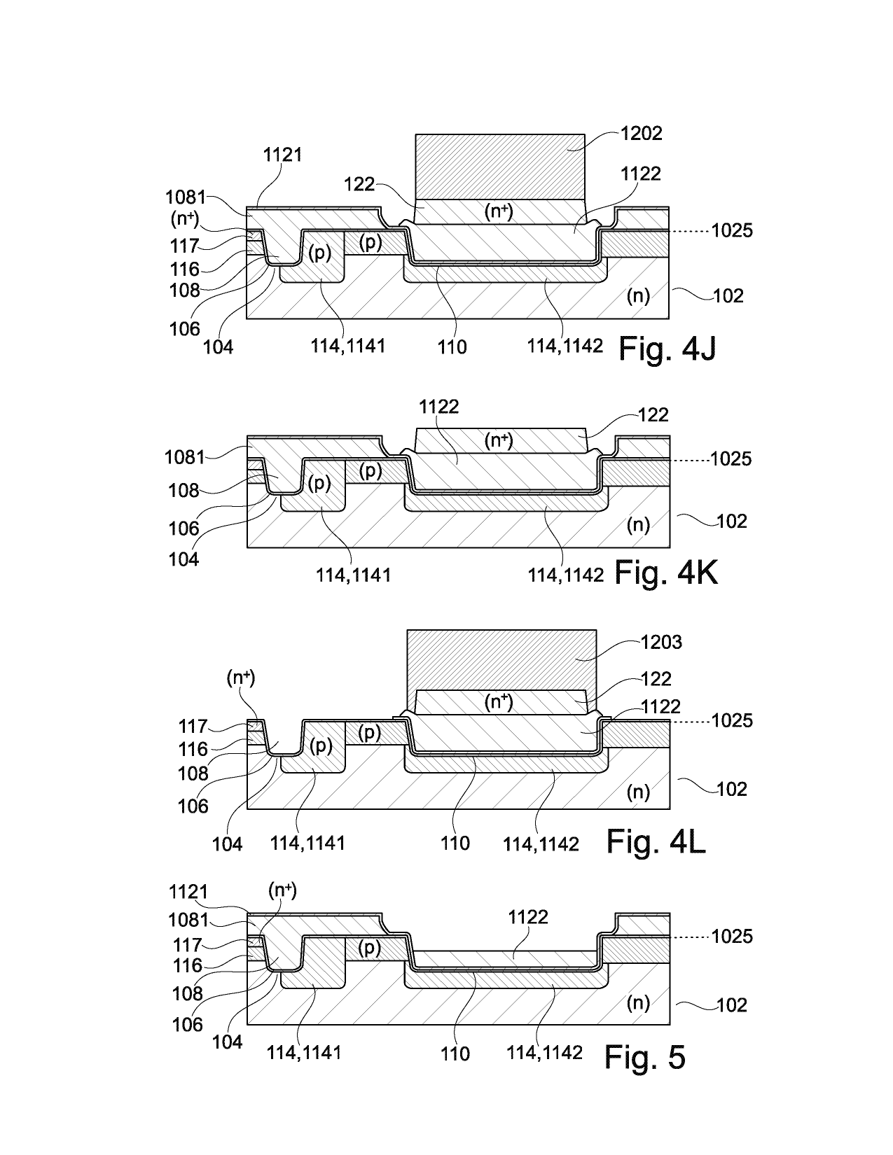

The schematic cross-sectional view of FIG. 5 may replace the process feature illustrated in FIG. 4G when manufacturing a semiconductor device as is illustrated in FIG. 2. In other words, the second dielectric layer 1122 is recessed to a larger extent than in FIG. 4G by adjusting a top side of the second dielectric layer 1122 below the first surface 1025. This may allow to arrange the sensor diode structure 113 completely or at least partly below the first surface 1025.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor device, comprising:
a silicon carbide (SiC) semiconductor substrate including a transistor cell area and a sensor area at a first surface of the SiC semiconductor substrate;
a gate trench in the transistor cell area;
a gate dielectric and a gate electrode in the gate trench;
a sensor trench in the sensor area;
a sensor trench dielectric at a bottom side of the sensor trench; and
a sensor diode structure on the sensor trench dielectric,
wherein a thickness of the sensor trench dielectric is larger than a thickness of the gate dielectric,
wherein a vertical distance from a bottom side of the sensor trench to the first surface is equal to or larger than a vertical distance from a bottom side of the gate trench to the first surface.

2. The semiconductor device of claim 1, wherein the sensor trench dielectric includes a first dielectric layer and a second dielectric layer, the first dielectric layer being arranged between the bottom side of the sensor trench and the second dielectric layer.

3. The semiconductor device of claim 2, wherein the first dielectric layer is a nitride layer and the second dielectric layer is an oxide layer.

4. The semiconductor device of claim 2, further comprising the gate dielectric arranged between the bottom side of the sensor trench and the first dielectric layer.

5. The semiconductor device of claim 1, further comprising a shielding layer structure, the shielding layer structure including a first part and a second part laterally spaced from one another, wherein the first part of the shielding layer structure adjoins the bottom side of the gate trench and the second part of the shielding layer structure adjoins the bottom side of the sensor trench.

6. The semiconductor device of claim 1, further comprising a first sensor pin and a second sensor pin, wherein the first and second sensor pins are each electrically isolated from pins of the transistor cell area.

7. The semiconductor device of claim 1, wherein the sensor diode structure includes a pn junction diode or a plurality of pn junction diodes electrically connected in series via anode to cathode.

8. The semiconductor device of claim 7, wherein each pn junction diode of the pn junction diode or the plurality of pn junction diodes is a lateral pn junction diode.

9. The semiconductor device of claim 1, wherein the sensor diode structure includes polycrystalline and/or amorphous silicon.

10. The semiconductor device of claim 9, wherein a top side of the polycrystalline and/or amorphous silicon is arranged at or below the first surface of the SiC semiconductor substrate.

11. The semiconductor device of claim 9, wherein the polycrystalline and/or amorphous silicon vertically extends from below the first surface of the SiC semiconductor substrate to over the first surface of the SiC semiconductor substrate.

12. The semiconductor device of claim 9, wherein a bottom side of the polycrystalline and/or amorphous silicon is arranged at or over the first surface of the SiC semiconductor substrate.

13. The semiconductor device of claim 9, further comprising an intermediate dielectric layer adjoining the first surface of the SiC semiconductor substrate, wherein a thickness of the polycrystalline and/or amorphous silicon is larger than a thickness of the intermediate dielectric layer.

14. The semiconductor device of claim 1, wherein the sensor diode structure is a temperature sensor device configured to measure a temperature of the semiconductor device.

15. The semiconductor device of claim 1, wherein a top side of the sensor diode structure is arranged over the first surface of the SiC semiconductor substrate.

16. A method of manufacturing a semiconductor device in a silicon carbide (SiC) semiconductor substrate including a transistor cell area and a sensor area at a first surface of the SiC semiconductor substrate, the method comprising:
forming a gate trench in the transistor cell area;
forming a gate dielectric and a gate electrode in the gate trench;
forming a sensor trench in the sensor area;
forming a sensor trench dielectric at a bottom side of the sensor trench; and
forming a sensor diode structure on the sensor trench dielectric,
wherein a thickness of the sensor trench dielectric is larger than a thickness of the gate dielectric,
wherein a vertical distance from a bottom side of the sensor trench to the first surface is equal to or larger than a vertical distance from a bottom side of the gate trench to the first surface.

17. The method of claim 16, wherein the gate trench and the sensor trench are concurrently formed.

18. The method of claim 16, further comprising:
forming a shielding layer structure including a first part and a second part laterally spaced from one another, the shielding layer structure being formed by at least one ion implantation process before forming the gate trench and the sensor trench,
wherein the first part of the shielding layer structure adjoins the bottom side of the gate trench and the second part of the shielding layer structure adjoins the bottom side of the sensor trench.

19. The method of claim 18, wherein the sensor trench dielectric is formed after forming the gate electrode, and wherein forming the sensor trench dielectric comprises forming a first dielectric layer and forming a second dielectric layer, the first dielectric layer being arranged between the bottom side of the sensor trench and the second dielectric layer.

20. The method of claim 19, further comprising:
etching a part of the second dielectric layer selective to the first dielectric layer.

21. The method of claim 20, wherein forming the sensor diode structure comprises:
forming a layer including polycrystalline and/or amorphous silicon over the sensor trench dielectric; and
etching a part of the layer including polycrystalline and/or amorphous silicon selective to the first dielectric layer.
